(19) United States
(12) Patent Application Publication
(10) Pub. No.: US 2026/0348735 A1
(43) Pub. Date: Nov. 5, 2026

(54) COMPUTATIONAL FLUID DYNAMICS TO MITIGATE LIQUID SURGE EFFECT

(71) Applicant: International Business Machines Corporation, Armonk, NY (US)

(72) Inventors: Irving A. DURAN, Dubuque, IA (US); Jacob Ryan JEPPERSON, St. Paul, MN (US); Michael BOONE, Lutz, FL (US); Tiberiu SUTO, Franklin, NY (US); Sarbajit Kumar RAKSHIT, Kolkata (IN)

(21) Appl. No.: 19/196,181

(22) Filed: May 1, 2025

(51) Int. Cl. G01C 21/34; B60P 3/22; G01C 21/36; G06F 30/28

(52) U.S. Cl. CPC G01C 21/3461; G01C 21/3691; G06F 30/28; B60P 3/2235

(57) ABSTRACT

Various aspects of the present disclosure generally relate to wireless communication. In some aspects, a device may simulate, using computational fluid dynamics (CFD), a liquid surge effect in a tank of a liquid transportation truck based on one or more conditions for stability of the truck and changes in a speed of the truck. The device may output a recommended acceleration rate and a recommended deceleration rate for the truck based on the simulated liquid surge effect. Numerous other aspects are described.

### BACKGROUND

This disclosure relates to fluid dynamics, and more specifically, to computations for liquid surges.

A liquid surge refers to the movement of liquid within a tank, often causing a wave effect, that can be dangerous and affect the handling of a vehicle. This surging can happen during acceleration, deceleration, cornering, or even due to wind, and can make the truck feel unstable or even lose control.

### SUMMARY

Some implementations described herein relate to a method. The method may include simulating, using computational fluid dynamics (CFD), a liquid surge effect in a tank of a liquid transportation truck based on one or more conditions for stability of the truck and changes in a speed of the truck. The method may include outputting a recommended acceleration rate and a recommended deceleration rate for the truck based on the simulated liquid surge effect.

Some implementations described herein relate to a computer system. The computer system may include a processor set, one or more computer-readable storage media; and program instructions stored on the one or more computer-readable storage media to cause the processor set to perform operations. The operations may comprise receiving an indication of a volume, a shape, and a size of a tank of a liquid transportation truck. The operations may comprise calculating a surge force exerted on the tank due to surge effects of liquid inside the tank, based on the indication and Navier-Stokes equations. The operations may comprise receiving an indication of speed changes and acceleration rates of the truck via a speedometer and a global positioning system. The operations may comprise estimating static electricity generated by turbulence of liquid in the tank during the speed changes. The operations may comprise determining a recommended acceleration rate and a recommended deceleration rate based on the calculated surge force, the indication of speed changes and acceleration rates, and the estimated static electricity. The operations may comprise outputting the recommended acceleration rate and the recommended deceleration rate.

Some implementations described herein relate to a computer program product. The computer program product may include one or more computer-readable storage media. The program instructions stored on the one or more computer-readable storage media may include integrating, using a CFD simulation, sensor data, and global positioning system (GPS) data from a liquid transportation truck with road condition data. The operations may include generating a safety score for a route of the truck based on the sensor data and that GPS data that is integrated with the CFD simulation. The operations may include outputting a recommended acceleration rate and a recommended deceleration rate for the route based on the generated safety score.

### BRIEF DESCRIPTION OF THE DRAWINGS

FIG. 1 is a diagram of an example computing environment for using computational fluid dynamics to mitigate surge effects in a liquid tank.

FIG. 2 illustrates various forces that can act on a liquid transportation truck and its tank during different driving scenarios.

FIG. 3 is a diagram of an example implementation associated with simulating a liquid surge effect to stabilize liquid transport vehicles.

FIG. 4 is a diagram illustrating an example of adjusting stopping distances.

FIG. 5 is a diagram illustrating an example of a sliding battery for stability control.

FIG. 6 is a flowchart of an example process associated with fluid dynamic computation to mitigate surge effect in liquid tank.

FIG. 7 is a flowchart of an example process associated with fluid dynamic computation to mitigate surge effect in liquid tank.

FIG. 8 is a flowchart of an example process associated with fluid dynamic computation to mitigate surge effect in liquid tank.

### DETAILED DESCRIPTION

The following detailed description of example implementations refers to the accompanying drawings. The same reference numbers in different drawings may identify the same or similar elements.

Transportation of liquid products (e.g., petroleum (gasoline), chemicals, or water) by road poses significant safety risks due to the dynamic movement of liquids within the tank, particularly during speed changes. Liquid surge effects within the tank can cause unbalanced forces, generating static electricity and increasing the risk of vehicle instability and potential fire hazards. Traditional methods of mitigating these risks have focused on optimizing tank design, but these methods often do not take into account the complex interactions between the liquid, tank, and vehicle dynamics.

Some implementations described herein provide a computer system that simulates liquid surge effects in a tank of a liquid transportation truck to optimize its acceleration and deceleration rates for stable transportation. For example, the computer system may simulate and determine, using computational fluid dynamics (CFD), a liquid surge effect in the tank based on conditions for stability of the truck (e.g., maximum allowable surge effect per direction) and changes in its speed. CFD is a branch of fluid mechanics that uses numerical analysis and algorithms to solve and analyze problems involving fluid flows. CFD relies on mathematical models to describe the behavior of fluids. The fundamental equations governing fluid flow are the Navier-Stokes equations, which are a set of nonlinear partial differential equations. These equations describe the conservation of mass, momentum, and energy in a fluid. The computer system may then output (e.g., transmit an indication for) recommended acceleration and deceleration rates for the truck based on the simulated liquid surge effect. For example, the truck may display an icon or information to the driver about the recommended acceleration and deceleration rates before and while the truck driver is adjusting a speed of the truck. In some implementations, the computer system may also transmit instructions to the truck computer such that the truck automatically adjusts the acceleration and deceleration of the truck, under the control and supervision of the truck driver.

In this way, the computing system provides dynamic safety management for transportation of liquid products by road by reducing computational complexity. For example, the computer system may efficiently simulate complex interactions between the liquid, tank, and vehicle dynamics under various road conditions to optimize acceleration and deceleration rates that minimize liquid surge effects. The computer system may also provide real-time adjustments to the recommended acceleration and deceleration rates based on sensor data and global positioning system (GPS) data. In this way, the computer system provides for safer transport of liquids and reduces the latency of information displayed to the truck driver.

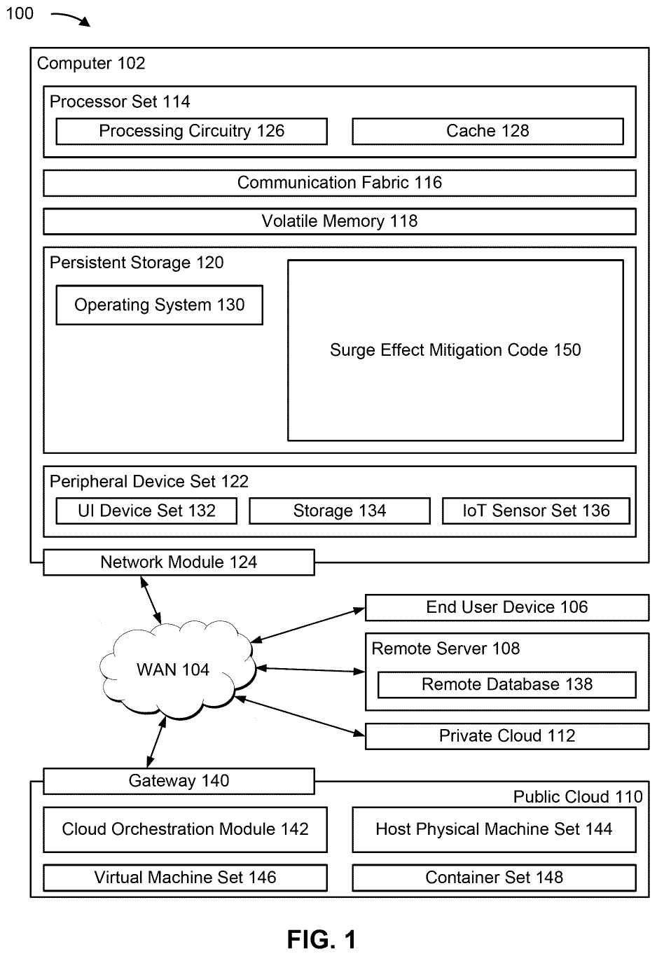

FIG. 1 is a diagram of an example computing environment 100 for using computational fluid dynamics to mitigate surge effects in a liquid tank.

The computing environment 100 contains an example of an environment for the execution of at least some of the computer code involved in performing the inventive methods, such as surge effect mitigation code 150. In addition to the surge effect mitigation code 150, the computing environment 100 includes, for example, a computer 102, a wide area network (WAN) 104, an end user device (EUD) 106, a remote server 108, a public cloud 110, and a private cloud 112. In this embodiment, the computer 102 includes a processor set 114 (including processing circuitry 126 and a cache 128), communication fabric 116, volatile memory 118, persistent storage 120 (including an operating system 130 and the surge effect mitigation code 150, as identified above), a peripheral device set 122 (including a user interface (UI) device set 132, storage 134, and an Internet of Things (IoT) sensor set 136), and a network module 124. The remote server 108 includes a remote database 138. The public cloud 110 includes a gateway 140, a cloud orchestration module 142, a host physical machine set 144, a virtual machine set 146, and a container set 148.

The computer 102 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as the remote database 138. As is well understood in the art of computer technology, and depending upon the technology, performance of a computer-implemented method may be distributed among multiple computers and/or between multiple locations. On the other hand, in this presentation of the computing environment 100, detailed discussion is focused on a single computer, specifically the computer 102, to keep the presentation as simple as possible. The computer 102 may be located in a cloud, even though it is not shown in a cloud in FIG. 1. On the other hand, the computer 102 is not required to be in a cloud except to any extent as may be affirmatively indicated.

Computer-readable program instructions are typically loaded onto the computer 102 to cause a series of operational steps to be performed by the processor set 114 of the computer 102 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as the cache 128 and the other storage media discussed below. The program instructions, and associated data, are accessed by the processor set 114 to control and direct performance of the inventive methods. In the computing environment 100, at least some of the instructions for performing the inventive methods may be stored in surge effect mitigation code 150 in the persistent storage 120.

The communication fabric 116 is the signal conduction path that allows the various components of the computer 102 to communicate with each other. Typically, this fabric is made of switches and electrically conductive paths, such as the switches and electrically conductive paths that make up buses, bridges, and/or physical input/output ports, among other examples. Other types of signal communication paths may be used, such as fiber optic communication paths and/or wireless communication paths, among other examples.

The volatile memory 118 is any type of volatile memory now known or to be developed in the future. Examples include dynamic type random access memory (RAM) or static type RAM. Typically, the volatile memory 118 is characterized by random access, but this is not required unless affirmatively indicated. In the computer 102, the volatile memory 118 is located in a single package and is internal to the computer 102, but, alternatively or additionally, the volatile memory 118 may be distributed over multiple packages and/or located externally with respect to the computer 102.

The code included in the surge effect mitigation code 150 typically includes at least some of the computer code involved in performing one or more operations described herein. The operations may include, for example, simulating, using CFD, a liquid surge effect in a tank of a liquid transportation truck based on one or more conditions for stability of the truck and changes in a speed of the truck. The operations may include outputting a recommended acceleration rate and a recommended deceleration rate for the truck based on the simulated liquid surge effect.

In some implementations, the operations may include receiving an indication of a volume, a shape, and a size of a tank of a liquid transportation truck. The operations may include calculating a surge force exerted on the tank due to surge effects of liquid inside the tank, based on the indication and Navier-Stokes equations. The operations may include receiving an indication of speed changes and acceleration rates of the truck via a speedometer and a global positioning system. The operations may include estimating static electricity generated by turbulence of liquid in the tank during the speed changes. The operations may include determining a recommended acceleration rate and a recommended deceleration rate based on the calculated surge force, the indication of speed changes and acceleration rates, and the estimated static electricity. The operations may include outputting the recommended acceleration rate and the recommended deceleration rate.

In some implementations, the operations may include integrating, using a CFD simulation, sensor data, and GPS data from a liquid transportation truck with road condition data. The operations may include generating a safety score for a route of the truck based on the sensor data and that GPS data that is integrated with the CFD simulation. The operations may include outputting a recommended acceleration rate and a recommended deceleration rate for the route based on the generated safety score.

The peripheral device set 122 includes the set of peripheral devices of the computer 102. Data communication connections between the peripheral devices and the other components of the computer 102 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, the UI device set 132 may include components such as a display screen, speaker, microphone, wearable devices (such as goggles and smart watches), keyboard, mouse, printer, touchpad, game controllers, and haptic devices. The storage 134 is external storage, such as an external hard drive, or insertable storage, such as an SD card. The storage 134 may be persistent and/or volatile. In some embodiments, the storage 134 may take the form of a quantum computing storage device for storing data in the form of qubits. In embodiments where the computer 102 is required to have a large amount of storage (for example, where the computer 102 locally stores and manages a large database), then this storage may be provided by peripheral storage devices designed for storing very large amounts of data, such as a storage area network (SAN) that is shared by multiple, geographically distributed computers. The IoT sensor set 136 is made up of sensors that can be used in Internet of Things applications. For example, one sensor may be a thermometer and another sensor may be a motion detector.

The network module 124 is the collection of computer software, hardware, and firmware that allows the computer 102 to communicate with other computers through the WAN 104. The network module 124 may include hardware, such as modems or Wi-Fi signal transceivers, software for packetizing and/or de-packetizing data for communication network transmission, and/or web browser software for communicating data over the internet. In some embodiments, network control functions and network forwarding functions of the network module 124 are performed on the same physical hardware device. In other embodiments (for example, embodiments that utilize software-defined networking (SDN)), the control functions and the forwarding functions of the network module 124 are performed on physically separate devices, such that the control functions manage several different network hardware devices. Computer-readable program instructions for performing the inventive methods can typically be downloaded to the computer 102 from an external computer or external storage device through a network adapter card or network interface included in the network module 124.

The WAN 104 is any wide area network (for example, the internet) capable of communicating computer data over non-local distances by any technology for communicating computer data, now known or to be developed in the future. In some embodiments, the WAN 104 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers, and/or edge servers, among other examples.

The EUD 106 is any computer system that is used and controlled by an end user (for example, a customer of an enterprise that operates the computer 102), and may take any of the forms discussed above in connection with the computer 102. The EUD 106 typically receives helpful and useful data from the operations of the computer 102. For example, in a hypothetical case where the computer 102 is designed to provide a recommendation to an end user, this recommendation would typically be communicated from the network module 124 of the computer 102 through the WAN 104 to the EUD 106. In this way, the EUD 106 can display, or otherwise present, the recommendation to an end user. In some embodiments, the EUD 106 may be a client device, such as thin client, heavy client, mainframe computer, and/or desktop computer, among other examples.

The remote server 108 is any computer system that serves at least some data and/or functionality to the computer 102. The remote server 108 may be controlled and used by the same entity that operates the computer 102. The remote server 108 represents the machine(s) that collect and store helpful and useful data for use by other computers, such as the computer 102. For example, in a hypothetical case where the computer 102 is designed and programmed to provide a recommendation based on historical data, then this historical data may be provided to the computer 102 from the remote database 138 of the remote server 108.

The public cloud 110 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of the public cloud 110 is performed by the computer hardware and/or software of the cloud orchestration module 142. The computing resources provided by the public cloud 110 are typically implemented by virtual computing environments that run on various computers making up the computers of the host physical machine set 144, which is the universe of physical computers in and/or available to the public cloud 110. The virtual computing environments (VCEs) typically take the form of virtual machines from the virtual machine set 146 and/or containers from the container set 148. It is understood that these VCEs may be stored as images and may be transferred among and between the various physical machine hosts, either as images or after instantiation of the VCE. The cloud orchestration module 142 manages the transfer and storage of images, deploys new instantiations of VCEs and manages active instantiations of VCE deployments. The gateway 140 is the collection of computer software, hardware, and firmware that allows the public cloud 110 to communicate through the WAN 104.

Some further explanation of VCEs will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

The private cloud 112 is similar to the public cloud 110, except that the computing resources are only available for use by a single enterprise. While the private cloud 112 is depicted as being in communication with the WAN 104, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, the public cloud 110 and the private cloud 112 are both part of a larger hybrid cloud.

Cloud computing services and/or microservices (not separately shown in FIG. 1): private cloud 112 and public clouds 110 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of application programming interfaces (APIs). One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

FIG. 1 is provided as an example. Other examples may differ from what is described with regard to FIG. 1.

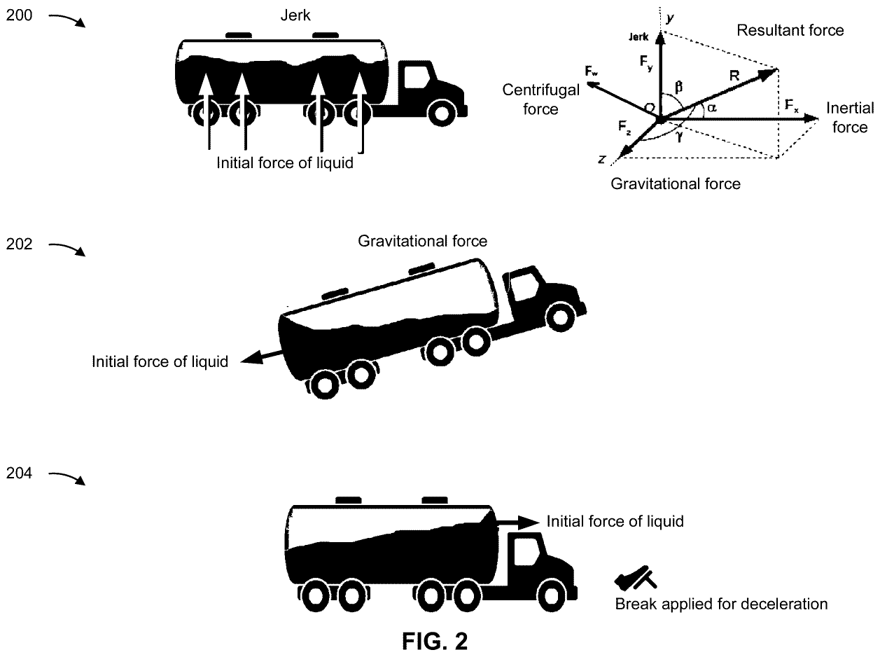

FIG. 2 illustrates various forces that can act on a liquid transportation truck and its tank during different driving scenarios. A tank of the truck may be partially full to allow for expansion or to meet a weight requirement. Partially filled tanks can involve liquids that move about within the tank with a large amount of mass due to inertial forces. Example 200 shows a jerk force that occurs due to sudden movements or changes in the road conditions. For example, when the truck encounters bumps or potholes, the liquid inside the tank can experience upward movements, causing a jerk force.

Example 202 shows a gravitational force that is due to an inclination of the road. When the truck is driving on an inclined road, the gravitational force acts on the liquid inside the tank, causing the liquid to shift and potentially create unbalanced forces.

Example 204 shows a braking force that is generated when the truck applies brakes. The sudden deceleration causes the liquid inside the tank to surge forward, creating a braking force that can impact the stability of the truck.

Other forces may include a centrifugal force. When the truck takes a turn, the liquid inside the tank experiences a centrifugal force that pushes the liquid towards the outer wall of the tank. This force is dependent on the speed of the truck and the radius of the turn. These forces can combine to create a resultant force that acts on the liquid inside the tank. The interaction of these forces can lead to complex liquid surge patterns, which can impact the stability and safety of the truck.

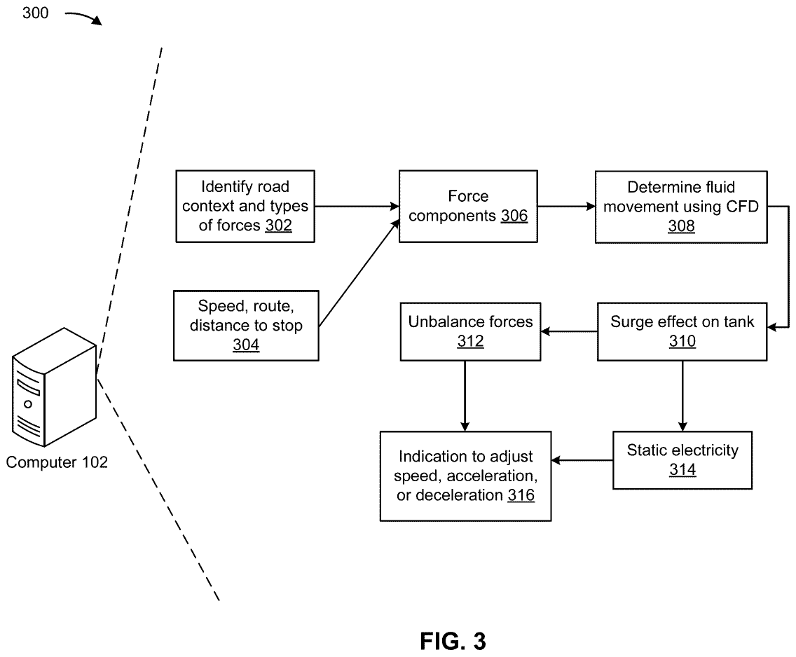

FIG. 3 is a diagram of an example implementation 300 associated with simulating a liquid surge effect to stabilize liquid transport vehicles. Implementation 300 involves a truck with a tank designed to hold liquid for transport. The truck is on a road that can be part of a selected route. The truck may have an onboard device or computer system (e.g., computer 102) or may be connected to a device or computer system that assists the driver with safely controlling the movement (e.g., speed, acceleration, deceleration, turns) of the truck so as to account for the fluid dynamics within the tank while the truck is driving on the road.

The computer system may simulate a liquid surge effect in the tank in order to determine actions that the truck or driver can take to stabilize liquid transport vehicles. The simulations may use three-dimensional generative adversarial network (3D-GAN) models that are trained by two networks, a generator and a discriminator, in opposition to each other. The generator creates 3D models, while the discriminator evaluates the models, providing feedback to improve the generator's output over time. The simulations may use CFD simulations that can be used to determine the surge effect within the tank and what can be done to mitigate this surge effect. For example, when a liquid transportation truck applies brakes suddenly, the liquid inside the tank surges forward, creating a braking force that can destabilize the truck. By simulating this surge effect using CFD, the computer system can determine the optimal deceleration rate that minimizes the unbalanced forces exerted on the tank walls. The computer system then outputs the recommended deceleration rate (e.g., dashboard icon, text display, or voice in the truck cab). This can help the driver ensure the truck maintains stability and reduces the risk of rollover or accidents during braking.

There may be multiple factors that affect the action that is to be taken to mitigate the surge effect of the liquid in the tank. As shown by 302, the computer system may identify a road context from cameras, sensors, GPS, or information that is received and/or stored. A road context may include a slickness of the road, an inclination of the road, and the effect of weather on the road. As shown by 304, the computer system may identify the speed of the truck, the route, the point in the route, curves in the road, or a distance needed to stop with respect to other vehicles, objects, or road signs. For example, the computer system may use a camera, an internet-of-things (IoT) device, and vehicle-to-everything (V2X) information to identify a contextual situation on the road that can add to forces on the liquid in the tank. The computer system may also collect information about the truck speed, road condition, curvature, inclination angle, distance to stop, and/or change in speed.

As shown by 306, the computer system may determine, from the information of 302 and 304, force components of for the types of forces caused by the road, such as jerk forces, gravitational forces, or centrifugal forces. As shown by 308, the computer system may perform one or more CFD simulations, based on the force components, the tank design, and the amount of liquid in the tank. As shown by 310, the computer system may use the CFD simulations to determine a surge effect of the force components. The surge effect may indicate unbalance forces, shown by 312, based on stability conditions, such as what forces the truck can withstand to maintain the safety and stability of the truck during movement on the road when accelerating, decelerating, or turning. As shown by 314, the computer system may use the CFD simulations to determine an amount of static electricity that could be generated by the movement of the liquid.

As shown by 316, the computer system may use the information about unbalance forces, static electricity, road context, sensors, GPS, route information, or any combination thereof to provide an indication for the truck driver. The indication may include a recommended deceleration rate, recommended acceleration rate, or a recommended speed. The indication may be an icon, a colored light, textual information, audio information, a tactical feel, or other indication to the truck driver that does not distract the driver but assists the driver. The indication may also include instructions to the truck computer to control, limit, modulate, or carry out the recommended acceleration and deceleration rates. Of course, this assistance supplements the truck driver's overall control and can be immediately overridden based on the judgement of the truck driver, the truck driver's employer, or another controlling entity.

In some implementations, the computer system may integrate sensor data (e.g., inertial sensors, tire traction sensors) and GPS data with CFD simulations. For example, the system may receive data from sensors and GPSs of trucks for multiple routes, integrate the data with CFD simulations to provide a safety score for each route, and select a route based on the safety scores. The sensor data may include information on the truck's speed, acceleration, and deceleration, as well as data from sensors monitoring the tank's pressure, temperature, and liquid level. The GPS data provides information on the truck's location, route, and road conditions.

The computer system may determine safety scores for different routes and select a route based on the safety scores. To calculate the safety scores of the various routes, the baseline score may start at 100 and the following route factors may be considered by the GPS routing system and will have the score reduced for each particular condition by a factor relative to the risk incurred by such condition: The route factors may include road conditions (e.g., highways and roads along route that are not well maintained and do not provide stable continuous traction), heavy traffic or known accident hotspots, adequate rest areas for drivers to take breaks to reduce fatigue-related accidents, good access to emergency services in case of an accident, or hazards or other adverse conditions a specific driver does not have a lot of experience handling. Other factors may include population density and building risk (e.g., routes that include highly populated areas or schools adjacent to the road, especially in combination with any other hazards) and environmental impact (e.g., in case of a spill, water sources or aquatic life that would be affected).

In an example, there may be three potential routes between a petroleum pickup point and a delivery location. A first route contains hazards 1, 2, 3, and 4 and warrants a safety score of 70. A second route contains hazards 1 and 3 and receives a safety score of 80. A third route contains hazards 6 and 7 and due to the high impact of these hazards, the third route receives a safety score of 30. In this case, the computer system may select the second route and the navigation system may give the driver additional prompts in order to mitigate the existing hazards in the second route.

Additionally, or alternatively, the computer system may perform simulations that include 3D-GAN models to determine surge effects in the tank, such that the computer system may determine an action that mitigates or neutralizes the surge effects. For example, a 3D-GAN model may be trained on a dataset of tank designs and operating conditions and used to accommodate a tank design to minimize surge effects. In some implementations, a computer system may also use this information and models to provide a tank design based on the historical information of trucks and liquid transport.

Additionally, or alternatively, the computer system may perform transient analysis to simulate dynamic behavior of liquid in the tank during acceleration, deceleration, and turning maneuvers. For example, the system may use CFD simulations to predict the impact of liquid sloshing on the structural integrity of tank walls and the overall stability of the truck.

In an example with a petroleum transportation truck, a computer system of the truck may consider the volume of petroleum in the tank, the ratio of filled petroleum to empty space in the tank, and the tank's design. If there is more empty space, the movement of liquid petroleum will also be more. Accordingly, the computer system may use CFD to identify the simulated liquid surge effect caused by changes in the truck's speed and select optimal deceleration and acceleration rates to ensure that the liquid surge effect does not create unbalanced forces on the petroleum transportation truck.

As the liquid surge effect in the petroleum tank can cause turbulence in the liquid, which in turn can generate static electricity, the computer system may use CFD to estimate the amount of static electricity generated in the petroleum due to simulated turbulence during speed changes. Based on a designed threshold value for static electricity, the computer system may determine permissible rates of acceleration and deceleration of the truck.

The computer system may have 3D model information for the tank design. The tank's shape and size influence how the liquid behaves inside the tank. The properties of the liquid being transported, such as density and viscosity, are known to the computer system. The computer system may use patterns of liquid surges on tank walls to determine unbalanced forces that are generated. The computer system may evaluate the liquid surge effect on the tank using Navier-Stokes equations, which describe the motion of fluid substances through nonlinear partial differential equations. The computer system may then dynamically select the appropriate acceleration and deceleration rates based on the road context and the evaluation of the motion of fluids and the corresponding fluid forces. The computer system may indicate the recommended acceleration and deceleration rates to the truck driver. As a result, the truck driver may drive the truck in a safer manner than if the driver did not have the recommendations.

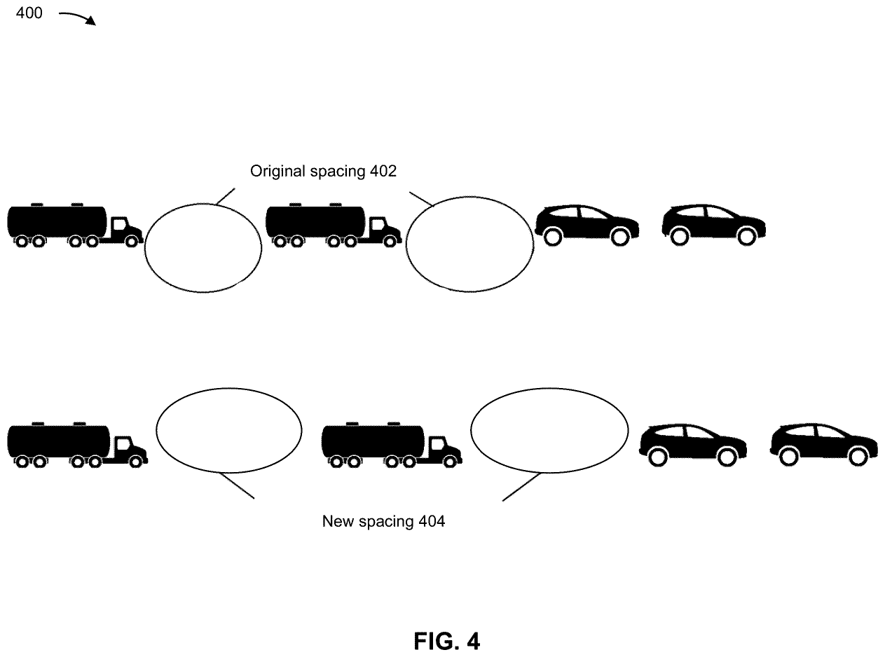

FIG. 4 is a diagram illustrating an example 400 of adjusting stopping distances. In some implementations, the computer system may determine safe distances from other vehicles based on the recommended acceleration rate and the recommended deceleration rate. The computer system may determine a safe distance further based on an identified fill level of the petroleum tank, a volume of petroleum being transported, and the current speed. The computer system may indicate the safe distance to the truck driver. For example, the computer system may output an indication of a safe distance to a navigation map display based on road conditions and one or more positions of other vehicles.

Example 400 shows an original spacing 402 and a new spacing 404 that follows an indication and a distance adjustment that is used to mitigate a surge effect of liquid in the tank. The computer system may also transmit a communication to other vehicles instructing the other vehicles to maintain a safe distance with respect to vehicles around the truck.

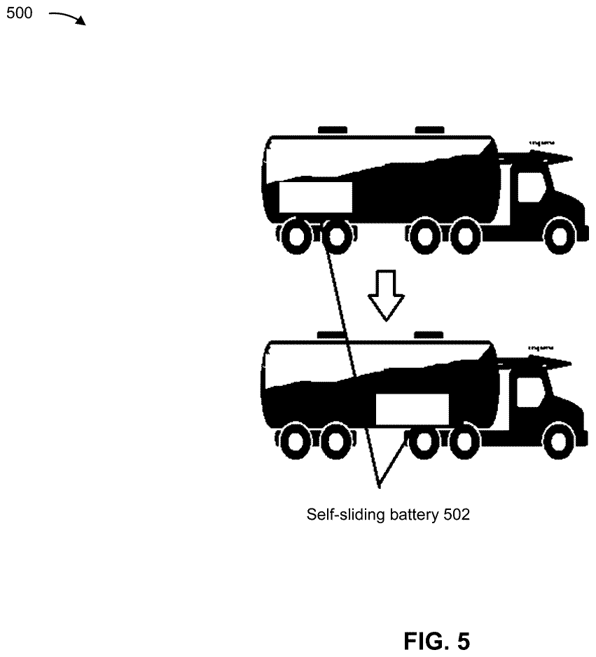

FIG. 5 is a diagram illustrating an example 500 of a sliding battery for stability control. In some implementations, the computer system may output, as the indication, instructions to control a self-sliding battery 502 that counterbalances unbalanced forces caused by liquid surge effects. For example, the computer system may output instructions for adjusting the position of the self-sliding battery based on an estimated unbalanced force generated by surge effects of liquid in the tank. This may be an automatic adjustment by the computer system that does not require the truck driver's input.

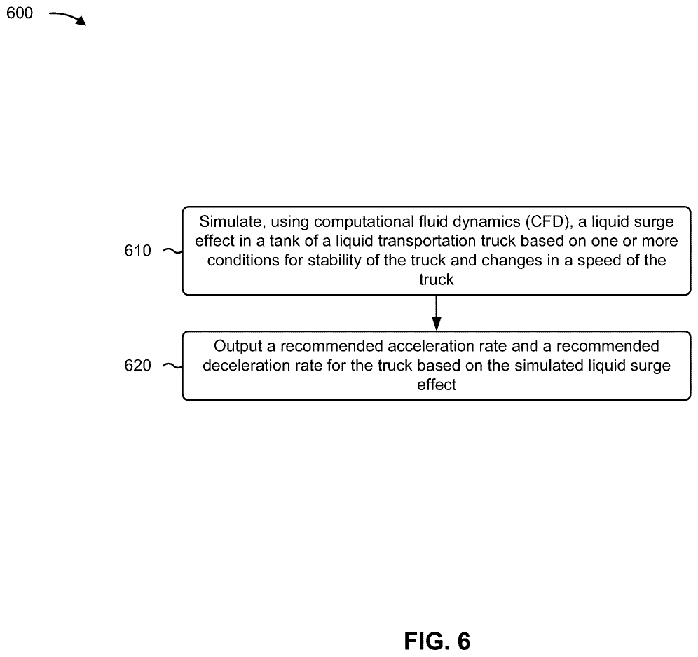

FIG. 6 is a flowchart of an example process 600 associated with fluid dynamic computation to mitigate surge effect in liquid tank. One or more process blocks of FIG. 6 are performed by a device (e.g., computer 102) and/or by another device or a group of devices separate from or including the device.

As shown in FIG. 6, process 600 includes simulating a liquid surge effect in a tank of a liquid transportation truck based on one or more conditions for stability of the truck and changes in a speed of the truck (block 610). For example, the device may simulate a liquid surge effect in a tank of a liquid transportation truck based on one or more conditions for stability of the truck and changes in a speed of the truck, as described above.

As further shown in FIG. 6, process 600 includes outputting a recommended acceleration rate and a recommended deceleration rate for the truck based on the simulated liquid surge effect (block 620). For example, the device may output a recommended acceleration rate and a recommended deceleration rate for the truck based on the simulated liquid surge effect, as described above.

Process 600 may include additional aspects, such as any single aspect or any combination of aspects described below and/or in connection with one or more other processes described elsewhere herein.

In a first implementation, process 600 includes receiving data from sensors and global positioning systems of trucks for multiple routes, integrating the data with CFD simulations to provide a safety score for each route, and selecting a route of the multiple routes based on the safety scores.

In a second implementation, alone or in combination with the first aspect, the one or more conditions for stability comprise minimization of risk of rollover, minimization of collisions with other vehicles, or minimization of hazards to pedestrians or building occupants along road periphery.

In a third implementation, alone or in combination with one or more of the first and second aspects, the truck is a liquid transportation truck or a chemical transportation truck.

In a fourth implementation, alone or in combination with one or more of the first through third aspects, process 600 includes identifying a tank design to minimize surge effects in the tank using an iterative 3D-GAN and CFD simulations of a flow pattern of liquid inside the tank.

In a fifth implementation, alone or in combination with one or more of the first through fourth aspects, process 600 includes outputting instructions to adjust a position of a self-sliding battery of the truck based on an estimated unbalanced force generated by surge effects of liquid in the tank.

In a sixth implementation, alone or in combination with one or more of the first through fifth aspects, process 600 includes estimating static electricity generated by turbulence of liquid in the tank during speed changes, and determining the recommended acceleration rate and the recommended deceleration rate in combination with unbalanced forces generated due to the turbulence.

In a seventh implementation, alone or in combination with one or more of the first through sixth aspects, process 600 includes determining a required safe distance from other vehicles based on the recommended acceleration rate, the recommended deceleration rate, and the speed of the truck.

In an eighth implementation, alone or in combination with one or more of the first through seventh aspects, process 600 includes evaluating liquid surge patterns on tank walls for road contexts that each include slickness, inclination, surface, and weather conditions, analyzing a context of a road on which the truck is driving, and determining the recommended acceleration rate and the recommended deceleration rate based on the CFD simulations and the context of the road.

In a ninth implementation, alone or in combination with one or more of the first through eighth aspects, process 600 includes calculating a force created on a tank wall of the truck due to a liquid surge effect of liquid in the tank during a speed change, and determining a surge of liquid in the tank based on aggregating possible forces applied on the liquid when the truck is moving.

In a tenth implementation, alone or in combination with one or more of the first through ninth aspects, process 600 includes adjusting the recommended acceleration rate and the recommended deceleration rate based on a combination of a calculated liquid surge effect and real-time data from one or more sensors and a GPS of the truck.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

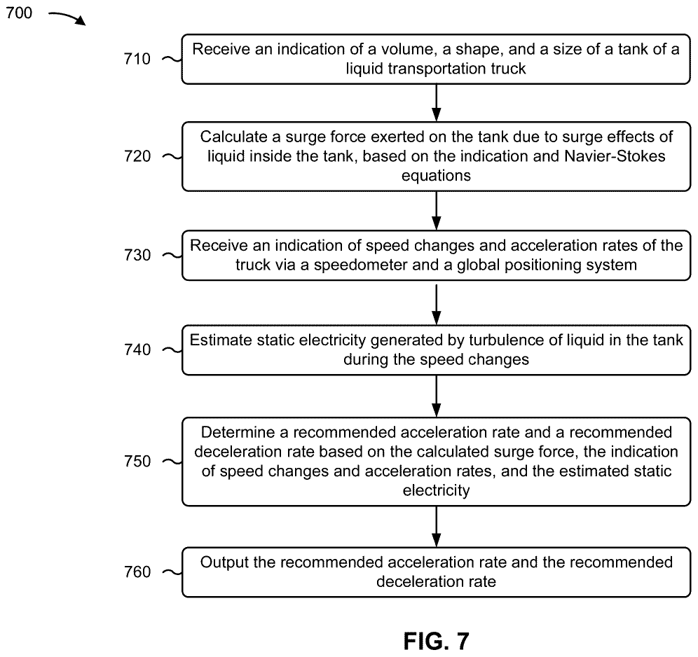

FIG. 7 is a flowchart of an example process 700 associated with fluid dynamic computation to mitigate surge effect in liquid tank. One or more process blocks of FIG. 7 are performed by a device (e.g., computer 102) and/or by another device or a group of devices separate from or including the device.

As shown in FIG. 7, process 700 includes receiving an indication of a volume, a shape, and a size of a tank of a liquid transportation truck (block 710). For example, the device may receive an indication of a volume, a shape, and a size of a tank of a liquid transportation truck, as described above.

As further shown in FIG. 7, process 700 includes calculating a surge force exerted on the tank due to surge effects of liquid inside the tank, based on the indication and Navier-Stokes equations (block 720). For example, the device may calculate a surge force exerted on the tank due to surge effects of liquid inside the tank, based on the indication and Navier-Stokes equations, as described above.

As further shown in FIG. 7, process 700 includes receiving an indication of speed changes and acceleration rates of the truck via a speedometer and a GPS (block 730). For example, the device may receive an indication of speed changes and acceleration rates of the truck via a speedometer and a GPS, as described above.

As further shown in FIG. 7, process 700 includes estimating static electricity generated by turbulence of liquid in the tank during the speed changes (block 740). For example, the device may estimate static electricity generated by turbulence of liquid in the tank during the speed changes, as described above.

As further shown in FIG. 7, process 700 includes determining a recommended acceleration rate and a recommended deceleration rate based on the calculated surge force, the indication of speed changes and acceleration rates, and the estimated static electricity (block 750). For example, the device may determine a recommended acceleration rate and a recommended deceleration rate based on the calculated surge force, the indication of speed changes and acceleration rates, and the estimated static electricity, as described above.

As further shown in FIG. 7, process 700 includes outputting the recommended acceleration rate and the recommended deceleration rate (block 760). For example, the device may output the recommended acceleration rate and the recommended deceleration rate, as described above.

Process 700 may include additional aspects, such as any single aspect or any combination of aspects described below and/or in connection with one or more other processes described elsewhere herein.

In a first implementation, the determining of the recommended acceleration rate and the recommended deceleration rate comprises determining the recommended acceleration rate and the recommended deceleration rate based on road context that includes a road slickness, a road inclination, a road surface, and weather conditions.

In a second implementation, alone or in combination with the first aspect, the operations comprise outputting instructions for adjusting a position of a self-sliding battery that counterbalances unbalanced forces cause by surge effects.

In a third implementation, alone or in combination with one or more of the first and second aspects, the operations comprise determining a safe distances from other vehicles, based on the recommended acceleration rate and the recommended deceleration rate, and outputting an indication of the safe distance.

In a fourth implementation, alone or in combination with one or more of the first through third aspects, the outputting of the indication of the safe distance comprises outputting an indication of the safe distance to a navigation map display based on road conditions and one or more positions of other vehicles.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

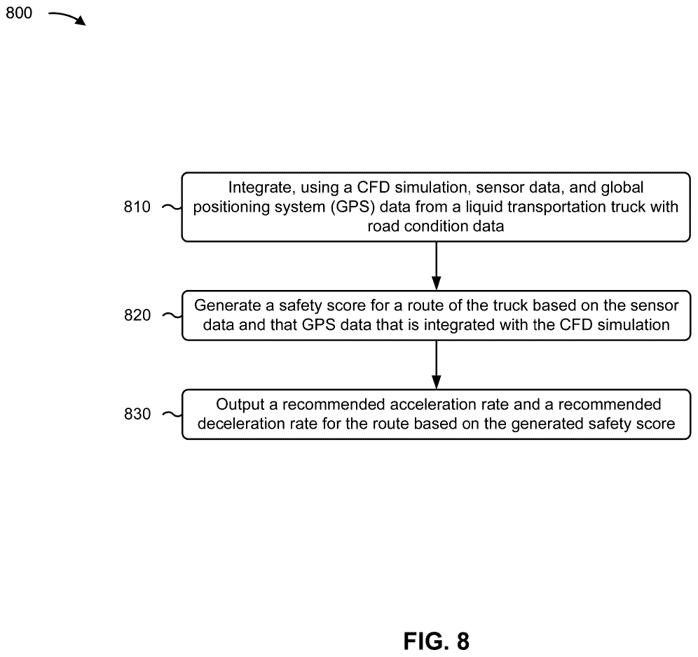

FIG. 8 is a flowchart of an example process 800 associated with fluid dynamic computation to mitigate surge effect in liquid tank. One or more process blocks of FIG. 8 are performed by a device (e.g., computer 102) and/or by another device or a group of devices separate from or including the device.

As shown in FIG. 8, process 800 includes integrating sensor data, and GPS data from a liquid transportation truck with road condition data (block 810). For example, the device may integrate sensor data, and GPS data from a liquid transportation truck with road condition data, as described above.

As further shown in FIG. 8, process 800 includes generating a safety score for a route of the truck based on the sensor data and that GPS data that is integrated with the CFD simulation (block 820). For example, the device may generate a safety score for a route of the truck based on the sensor data and that GPS data that is integrated with the CFD simulation, as described above.

As further shown in FIG. 8, process 800 includes outputting a recommended acceleration rate and a recommended deceleration rate for the route based on the generated safety score (block 830). For example, the device may output a recommended acceleration rate and a recommended deceleration rate for the route based on the generated safety score, as described above.

Process 800 may include additional aspects, such as any single aspect or any combination of aspects described below and/or in connection with one or more other processes described elsewhere herein.

In a first implementation, the using the CFD simulation comprises simulating a liquid surge effect in a tank of the truck based on road context, and process 800 includes determining the recommended acceleration rate and the recommended deceleration rate based on the liquid surge effect and unbalanced forces that are generated due to turbulence of liquid in the tank.

In a second implementation, alone or in combination with the first aspect, the using the CFD simulation comprises generating a 3D model of a tank of the truck, simulating flow patterns of liquid in the tank under various operating conditions, and identifying points of liquid turbulence and pressure distribution within the tank.

In a third implementation, alone or in combination with one or more of the first and second aspects, the using the CFD simulation comprises performing transient analysis to simulate dynamic behavior of liquid in a tank of the truck during acceleration, deceleration, and turning maneuvers, and predicting an impact of liquid sloshing on a structural integrity of tank walls and an overall stability of the truck.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

The foregoing disclosure provides illustration and description, but is not intended to be exhaustive or to limit the implementations to the precise forms disclosed. Modifications may be made in light of the above disclosure or may be acquired from practice of the implementations. For example, various aspects of this disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

A computer program product embodiment (“CPP embodiment” or “CPP”) is a term used in this disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, RAM, ROM, erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc), or any suitable combination of the foregoing. A computer-readable storage medium, as that term is used in this disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

As used herein, the term “component” is intended to be broadly construed as hardware, firmware, or a combination of hardware and software. It will be apparent that systems and/or methods described herein may be implemented in different forms of hardware, firmware, and/or a combination of hardware and software. The actual specialized control hardware or software code used to implement these systems and/or methods is not limiting of the implementations. Thus, the operation and behavior of the systems and/or methods are described herein without reference to specific software code-it being understood that software and hardware can be used to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When “a processor” or “one or more processors” (or another device or component, such as “a controller” or “one or more controllers”) is described or claimed (within a single claim or across multiple claims) as performing multiple operations or being configured to perform multiple operations, this language is intended to broadly cover a variety of processor architectures and environments. For example, unless explicitly claimed otherwise (e.g., via the use of “first processor” and “second processor” or other language that differentiates processors in the claims), this language is intended to cover a single processor performing or being configured to perform all of the operations, a group of processors collectively performing or being configured to perform all of the operations, a first processor performing or being configured to perform a first operation and a second processor performing or being configured to perform a second operation, or any combination of processors performing or being configured to perform the operations. For example, when a claim has the form “one or more processors configured to: perform X; perform Y; and perform Z,” that claim should be interpreted to mean “one or more processors configured to perform X; one or more (possibly different) processors configured to perform Y; and one or more (also possibly different) processors configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method comprising:
simulating, using computational fluid dynamics (CFD), a liquid surge effect in a tank of a liquid transportation truck based on one or more conditions for stability of the truck and changes in a speed of the truck; and
outputting a recommended acceleration rate and a recommended deceleration rate for the truck based on the simulated liquid surge effect.

2. The method of claim 1, further comprising:
receiving data from sensors and global positioning systems of trucks for multiple routes;
integrating the data with CFD simulations to provide a safety score for each route; and
selecting a route of the multiple routes based on the safety scores.

3. The method of claim 1, wherein the one or more conditions for stability comprise minimization of risk of rollover, minimization of collisions with other vehicles, or minimization of hazards to pedestrians or building occupants along road periphery.

4. The method of claim 1, wherein the truck is a liquid transportation truck or a chemical transportation truck.

5. The method of claim 1, further comprising:
identifying a tank design to minimize surge effects in the tank using an iterative three-dimensional generative adversarial network and CFD simulations of a flow pattern of liquid inside the tank.

6. The method of claim 1, further comprising:
outputting instructions to adjust a position of a self-sliding battery of the truck based on an estimated unbalanced force generated by surge effects of liquid in the tank.

7. The method of claim 1, further comprising:
estimating static electricity generated by turbulence of liquid in the tank during speed changes; and
determining the recommended acceleration rate and the recommended deceleration rate in combination with unbalanced forces generated due to the turbulence.

8. The method of claim 1, further comprising:
determining a required safe distance from other vehicles based on the recommended acceleration rate, the recommended deceleration rate, and the speed of the truck.

9. The method of claim 1, further comprising:
evaluating liquid surge patterns on tank walls for road contexts that each include slickness, inclination, surface, and weather conditions;
analyzing a context of a road on which the truck is driving; and
determining the recommended acceleration rate and the recommended deceleration rate based on the CFD simulations and the context of the road.

10. The method of claim 1, further comprising:
calculating a force created on a tank wall of the truck due to a liquid surge effect of liquid in the tank during a speed change; and
determining a surge of liquid in the tank based on aggregating possible forces applied on the liquid when the truck is moving.

11. The method of claim 1, further comprising:
adjusting the recommended acceleration rate and the recommended deceleration rate based on a combination of a calculated liquid surge effect and real-time data from one or more sensors and a global positioning system of the truck.

12. A computer system comprising:
a processor set;
one or more computer-readable storage media; and
program instructions stored on the one or more computer-readable storage media to cause the processor set to perform operations, the operations comprising:
receiving an indication of a volume, a shape, and a size of a tank of a liquid transportation truck;
calculating a surge force exerted on the tank due to surge effects of liquid inside the tank, based on the indication and Navier-Stokes equations;
receiving an indication of speed changes and acceleration rates of the truck via a speedometer and a global positioning system;
estimating static electricity generated by turbulence of liquid in the tank during the speed changes;
determining a recommended acceleration rate and a recommended deceleration rate based on the calculated surge force, the indication of speed changes and acceleration rates, and the estimated static electricity; and
outputting the recommended acceleration rate and the recommended deceleration rate.

13. The computer system of claim 12, wherein the determining of the recommended acceleration rate and the recommended deceleration rate comprises determining the recommended acceleration rate and the recommended deceleration rate based on road context that includes a road slickness, a road inclination, a road surface, and weather conditions.

14. The computer system of claim 12, wherein the operations comprise:
outputting instructions for adjusting a position of a self-sliding battery that counterbalances unbalanced forces cause by surge effects.

15. The computer system of claim 12, wherein the operations comprise:
determining a safe distances from other vehicles, based on the recommended acceleration rate and the recommended deceleration rate; and
outputting an indication of the safe distance.

16. The computer system of claim 15, wherein the outputting of the indication of the safe distance comprises outputting an indication of the safe distance to a navigation map display based on road conditions and one or more positions of other vehicles.

17. A computer program product comprising:
one or more computer-readable storage media; and
program instructions stored on the one or more computer-readable storage media to perform operations, the operations comprising:
integrating, using a computational fluid dynamics (CFD) simulation, sensor data, and global positioning system (GPS) data from a liquid transportation truck with road condition data;
generating a safety score for a route of the truck based on the sensor data and that GPS data that is integrated with the CFD simulation; and
outputting a recommended acceleration rate and a recommended deceleration rate for the route based on the generated safety score.

18. The computer program product of claim 17, wherein the using the CFD simulation comprises simulating a liquid surge effect in a tank of the truck based on road context, and wherein the operations further comprise determining the recommended acceleration rate and the recommended deceleration rate based on the liquid surge effect and unbalanced forces that are generated due to turbulence of liquid in the tank.

19. The computer program product of claim 17, wherein the using the CFD simulation comprises:
generating a three-dimensional model of a tank of the truck;
simulating flow patterns of liquid in the tank under various operating conditions; and
identifying points of liquid turbulence and pressure distribution within the tank.

20. The computer program product of claim 17, wherein the using the CFD simulation comprises:
performing transient analysis to simulate dynamic behavior of liquid in a tank of the truck during acceleration, deceleration, and turning maneuvers; and
predicting an impact of liquid sloshing on a structural integrity of tank walls and an overall stability of the truck.
